(19) United States
(12) Patent Application Publication
(10) Pub. No.: US 2024/0213071 A1
(43) Pub. Date: Jun. 27, 2024

(54) ELECTROSTATIC CHUCK

(71) Applicant: SAMSUNG ELECTRONICS CO., LTD., Suwon-si (KR)

(72) Inventors: Junho IM, SUWON-SI (KR); Younseon Wang, SUWON-SI (KR); Yongwoo Kim, SUWON-SI (KR); Taehwa Kim, SUWON-SI (KR); Inseok Seo, SUWON-SI (KR); Kiseok Lee, SUWON-SI (KR)

(21) Appl. No.: 18/396,553

(22) Filed: Dec. 26, 2023

(30) Foreign Application Priority Data
Dec. 27, 2022 (KR) 10-2022-0186151

(51) Int. Cl. H01L 21/683; H01J 37/32

(52) U.S. Cl. CPC H01L 21/6833; H01J 37/32715

(57) ABSTRACT

An electrostatic chuck includes an electrostatic chuck body having a step portion protruding from a lower end, an adhesive layer disposed on an upper surface of the electrostatic chuck body, a ceramic puck adhered to the adhesive layer and having an edge protruding from the upper surface of the electrostatic chuck body, and a sealant disposed between the step portion and the edge of the ceramic puck and configured to block reaction gas from permeating into the adhesive layer. The sealant includes a coating layer disposed on an external surface thereof, and the coating layer includes a metal oxide including a single rare earth oxide and/or a multilayer heterogeneous metal oxide.

### CROSS-REFERENCE TO RELATED APPLICATION(S)

This application claims priority under 35 U.S.C. § 119(a) to Korean Patent Application No. 10-2022-0186151 filed on Dec. 27, 2022 in the Korean Intellectual Property Office, the entire disclosure of which is herein incorporated by reference.

### TECHNICAL FIELD

The present inventive concept relates to an electrostatic chuck.

### DISCUSSION OF THE RELATED ART

Semiconductor devices and/or display devices may be manufactured by stacking and patterning a plurality of thin film layers, including a dielectric layer and a metal layer, on a glass substrate, a flexible substrate, a semiconductor wafer substrate, or the like, through semiconductor processes such as a chemical vapor deposition (CVD) process, a physical vapor deposition (PVD) process, an ion implantation process, an etching process, and the like.

The chamber device for performing these semiconductor processes may include an Electrostatic Chuck (ESC) supporting various substrates such as glass substrates, flexible substrates, and semiconductor wafer substrates. These ESCs may fix the substrates using electrostatic force. In addition, the electrostatic chuck includes a sealant for protecting the adhesive layer for bonding the ceramic plate on which the substrate is seated.

However, there is a problem in which the sealant needs to be replaced after a certain period of time due to etching of the sealant as the process progresses. In addition, there may be a problem in that the edge temperature of the ceramic plate rises due to the sealant formed of a material with relatively low thermal conductivity, resulting in a defective edge yield of the substrate.

### SUMMARY

An electrostatic chuck includes an electrostatic chuck body having a step portion protruding from a lower end thereof. An adhesive layer is disposed on an upper surface of the electrostatic chuck body. A ceramic puck is adhered to the adhesive layer and has an edge protruding from the upper surface of the electrostatic chuck body. A sealant is disposed between the step portion and the edge of the ceramic puck and is configured to block reaction gas from permeating into the adhesive layer. The sealant includes a coating layer disposed on an external surface thereof, and the coating layer includes a metal oxide including a single rare earth oxide and/or a multilayer heterogeneous metal oxide.

### BRIEF DESCRIPTION OF DRAWINGS

The above and other aspects, features, and aspects of the present inventive concept will be more clearly understood from the following detailed description, taken in conjunction with the accompanying drawings, in which:

FIG. 1 is a configuration diagram illustrating an etching apparatus including an electrostatic chuck according to example embodiments;

FIG. 2 is an enlarged view illustrating part A of FIG. 1;

FIG. 3 is an enlarged view illustrating part B of FIG. 2;

FIG. 4 is a perspective view illustrating a sealant provided in an electrostatic chuck according to an example embodiment;

FIG. 5 is a perspective view illustrating a sealant provided in an electrostatic chuck according to an example embodiment;

FIG. 6 is a configuration diagram illustrating an electrostatic chuck according to an example embodiment;

FIG. 7 is a configuration diagram illustrating an electrostatic chuck according to an example embodiment;

FIG. 8 is a configuration diagram illustrating an electrostatic chuck according to an example embodiment; and

FIG. 9 is a configuration diagram illustrating an electrostatic chuck according to an example embodiment.

### DETAILED DESCRIPTION

Hereinafter, example embodiments will be described with reference to the accompanying drawings.

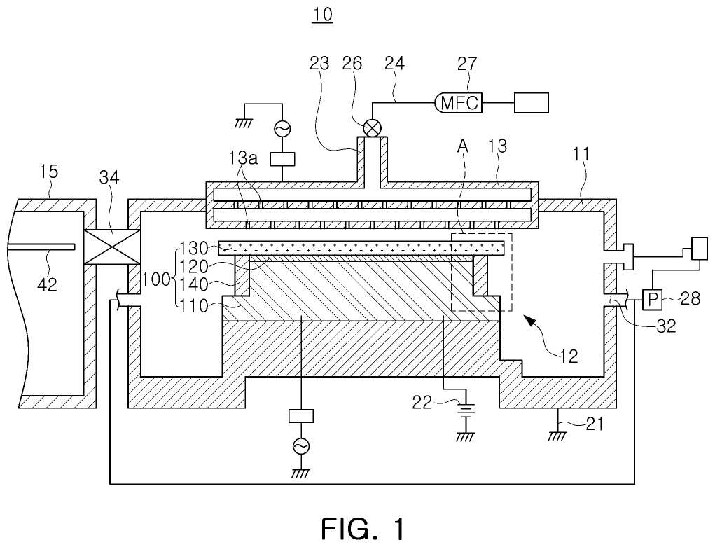

FIG. 1 is a configuration diagram illustrating an etching apparatus according to example embodiments.

Referring to FIG. 1, an etching apparatus 10 includes a reaction chamber 11 in which a wafer is loaded. The reaction chamber 11 provides a space for performing an etching process on the loaded wafer, and includes a susceptor 12 having an electrostatic chuck 100 on which a wafer is seated, and an upper electrode 13 disposed on the susceptor 12. Each of the susceptor 12 and the upper electrode 13 has a substantially cylindrical shape, and the reaction chamber 11 may be electrically grounded through a ground line 21.

The electrostatic chuck 100 is disposed in an upper portion of the susceptor 12 to fix the wafer. The electrostatic chuck 100 includes two polyimide-based films and a conductive thin film disposed therebetween. The conductive thin film is electrically connected to a high-voltage DC power source 22 disposed outside the reaction chamber 11.

When a predetermined voltage from the high-voltage DC power source 22 is applied to the conductive thin film, charge is generated on the surface of the polyimide-based film to generate a Coulomb force that fixes the wafer to the upper surface of the electrostatic chuck 100. However, the method of fixing the wafer is not necessarily limited to the method using an electrostatic chuck. A method of fixing the wafer using a mechanical device such as a clamp may also be used.

The upper electrode 13 is disposed on an upper portion of the electrostatic chuck 100 to face the susceptor 12. The lower end of the upper electrode 13 may be formed of silicon to stabilize the atmosphere inside the reaction chamber 11 during an etching process. Silicon may have a thickness sufficient for high-frequency power used for plasma etching to pass therethrough. In addition thereto, the upper electrode 13 may include parts formed of aluminum or anodized aluminum.

A gas inlet 23 for supplying gases for an etching process is disposed in an upper portion of the upper electrode 13. The gas inlet 23 is connected to a reaction gas supply source 25 through a gas supply line 24, and a mass flow controller (MFC, 27) and a valve 26 for controlling the flow rate are disposed on the gas supply line 24. In this case, the upper electrode 13 may be a path for supplying the reaction gas into the reaction chamber 11. To this end, the upper electrode 13 may be comprised of a plurality of layers having a plurality of diffusion holes 13a. Also, the lower end of the upper electrode 13 may have a shower head structure and a hollow structure for uniform gas distribution.

The reaction chamber 11 is connected to a predetermined pressure reducing device 28 (e.g., a vacuum pump) through an exhaust pipe 32 disposed in a predetermined area. Accordingly, the reaction chamber 11 may provide a relatively low internal pressure required for excellent etching characteristics. A gate valve 34 is disposed on the sidewall of the reaction chamber 11, and a load lock chamber 15 in which a wafer transfer arm 42 is disposed is connected to the gate valve 34.

Looking at the operation of carrying the wafer into the reaction chamber 11, after reducing the pressure of the load lock chamber 15 to a similar magnitude to a magnitude of the reaction chamber 11, the wafer is transferred from the load lock chamber 15 to the reaction chamber 11 using the wafer transfer arm 42. Thereafter, after the wafer transfer arm 42 is exported from the reaction chamber 11 to the load lock chamber 15, the gate valve 34 is closed.

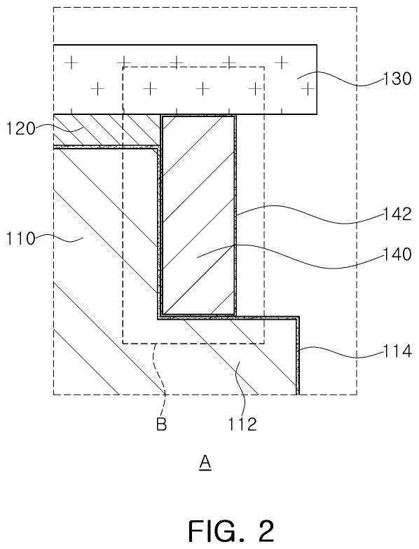

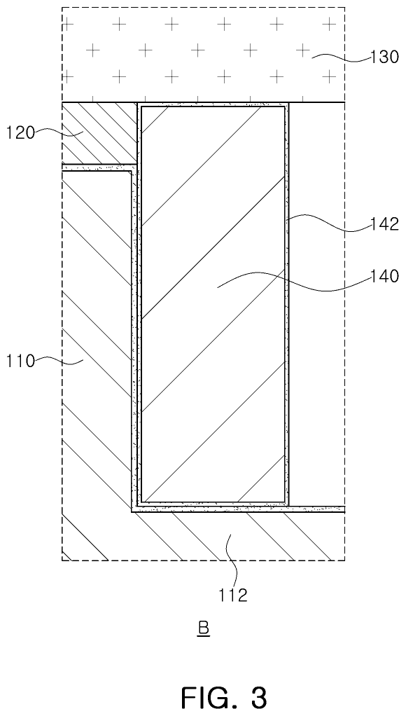

FIG. 2 is an enlarged view illustrating part A of FIG. 1, and FIG. 3 is an enlarged view illustrating part B of FIG. 2.

Referring to FIGS. 2 and 3, the electrostatic chuck 100, according to an example embodiment, includes an electrostatic chuck body 110, an adhesive layer 120, a ceramic puck 130, and a sealant 140.

The electrostatic chuck body 110 may have a step portion 112 protruding in a radial direction on a lower end thereof. As an example, the electrostatic chuck body 110 may be formed of aluminum. As an example, a protective layer 114 may be provided on the surface of the electrostatic chuck body 110. The protective layer 114 may be formed of, for example, aluminum oxide.

The adhesive layer 120 is disposed on the upper surface of the electrostatic chuck body 110. As an example, the adhesive layer 120 bonds the ceramic puck 130 to the upper portion of the electrostatic chuck body 120. The adhesive layer 120 may be a ceramic bond.

The ceramic puck 130 is adhered to the adhesive layer 120 and is disposed such that an edge thereof protrudes from the upper surface of the electrostatic chuck body 110. As an example, a wafer is seated on the upper surface of the ceramic puck 130 during the process.

The sealant 140 is disposed between the step portion 112 and the edge of the ceramic puck 130 to prevent the reaction gas from permeating into the adhesive layer 120. As an example, the sealant 140 may be formed of a metal material, a ceramic material, a metal-ceramic composite, and/or a polymer-ceramic composite. When the sealant 140 is formed of a metal material, the sealant 140 may be formed of aluminum and/or stainless steel. When the sealant 140 is formed of a ceramic material, the sealant 140 may be formed of aluminum nitride (AlN), aluminum oxide (Al₂O₃), yttrium oxide (Y₂O₃), silicon oxide (SiO₂), silicon carbide (SiC), and/or Yttrium Aluminum Garnet (YAG). When the sealant 140 is formed of a metal-ceramic composite, the sealant 140 may be formed of an aluminum-silicon carbide composite material. When the sealant 140 includes a polymer-ceramic composite, the sealant 140 may include a silicon-aluminum oxide composite and/or a silicon-aluminum nitride composite.

The sealant 140 may be provided with a coating layer 142 on the outer surface. As an example, the coating layer 142 may include a metal oxide (Al₂O₃, Y₂O₃, YAG, ZrO₂ , TiO₂, etc.) including a single rare earth oxide, and/or a multilayer heterogeneous metal oxide (Al₂O₃—Y₂O₃, Al₂O₃—TiO₂, etc.).

The coating layer 142 may be formed through an atomic layer deposition process or a chemical vapor deposition process. As an example, when manufacturing the electrostatic chuck 100, the sealant 140 is installed between the electrostatic chuck body 110 and the ceramic puck 130, and then the coating layer 142 may be formed by atomic layer deposition (ALD). At this time, the coating layer 142 may be deposited on the sealant 140 by supplying a coating material in the form of a gas. Accordingly, the coating layer 142 may be formed to block a space between the sealant 140 and the ceramic puck 130 and a space between the sealant 140 and the electrostatic chuck body 110.

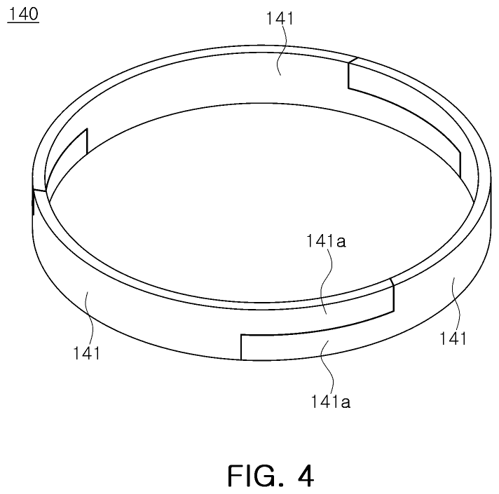

The sealant 140 may have a circular ring shape, and as an example, a cross-section thereof may have a rectangular shape. In addition, the sealant 140 is inserted into a space on the step portion 112 of the electrostatic chuck body 110 and below the edge of the ceramic puck 130 to prevent reaction gas from permeating into the adhesive layer 120. As illustrated in more detail in FIG. 4, the sealant 140 may have a circular annular shape formed of a plurality of seals 141. As an example, the plurality of seals 141 may have coupling portions 141a formed stepwise on mutually coupled portions. For example, the plurality of seals 141 may be comprised of three, and the coupling portions 141a may be provided on both ends of the three seals 141. In addition, the plurality of seals 141 may be coupled as the coupling portions 141a facing each other are displaced vertically.

As described above, since the sealant 140 includes a metal material, a ceramic material, a metal-ceramic composite, and/or a polymer-ceramic composite, thermal conductivity may be increased and corrosion resistance may be increased. Accordingly, the replacement frequency of the sealant 140 may be reduced. In addition, the temperature at the edge of the electrostatic chuck 100 may be prevented from excessively rising. In addition, since the coating layer 142 is provided on the outer surface of the sealant 140, the contact area between the sealant 140, the electrostatic chuck body 120, and the ceramic puck 130 is increased, and thus, thermal conductivity may be increased. Furthermore, permeation of reactive gas into the adhesive layer 120 may be prevented.

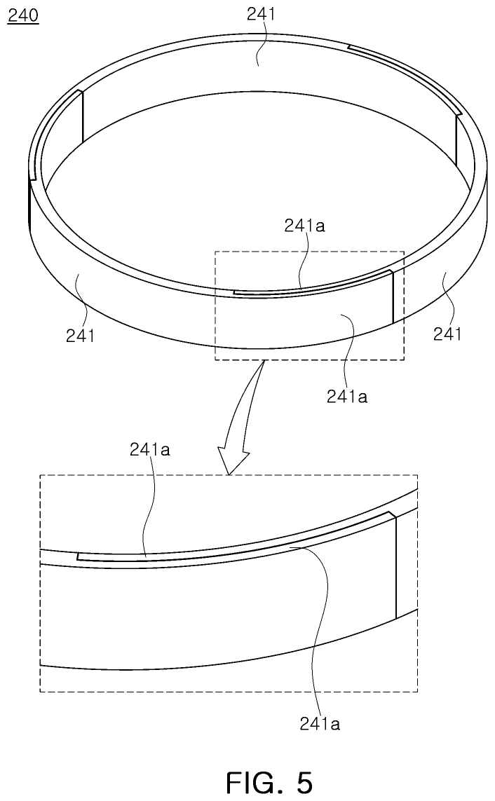

FIG. 5 is a perspective view illustrating a sealant provided in an electrostatic chuck according to an example embodiment.

Referring to FIG. 5, the sealant 240 may have a circular annular shape formed of a plurality of seals 241. As an example, the plurality of seals 241 may have coupling portions 241a formed stepwise on mutually coupled portions. For example, the plurality of seals 241 may include three, and coupling portions 241a may be disposed on opposite ends of the three seals 241. In addition, the plurality of seals 141 may be coupled as the coupling portions 241a facing each other are displaced in the thickness direction of the sealant 240. In detail, the coupling portions 241a may be disposed to overlap each other in the thickness direction of the sealant 240.

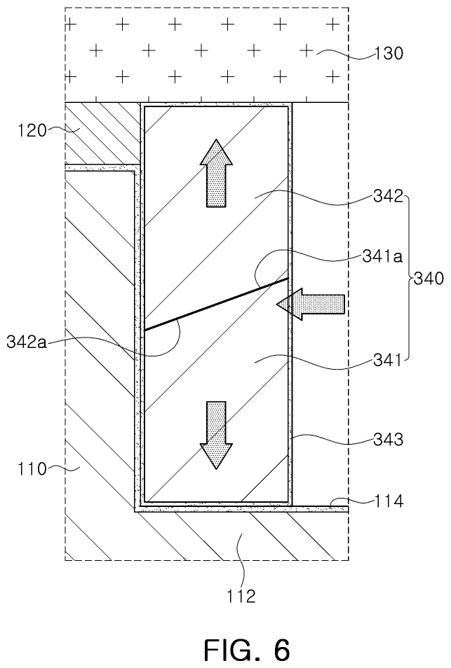

FIG. 6 is a configuration diagram illustrating an electrostatic chuck according to an example embodiment.

Referring to FIG. 6, a sealant 340 may include a first sealant 341 provided with a first inclined surface 341a on the upper end and a second sealant 342 provided with a second inclined surface 342a on the lower end. The first inclined surface 341a and the second inclined surface 342a may be in contact with each other. As an example, in the installation of the sealant 340, the second sealant 342 is first mounted between the ceramic puck 130 and the step portion 112 of the electrostatic chuck body 110, and then the first sealant 341 may be installed by being inserted into the lower portion of the second sealant 342. Then, a coating layer 343 may be formed on the sealant 340. In this manner, the sealant 340 is installed in such a manner that the first inclined surface 341a and the second inclined surface 342a come into contact with each other. Therefore, the first sealant 341 generates a pressing force toward the step portion 112, and the second sealant 342 may generate a pressing force toward the ceramic puck 130. Accordingly, the sealant 340 may be more firmly installed between the ceramic puck 130 and the step portion 112 of the electrostatic chuck body 110.

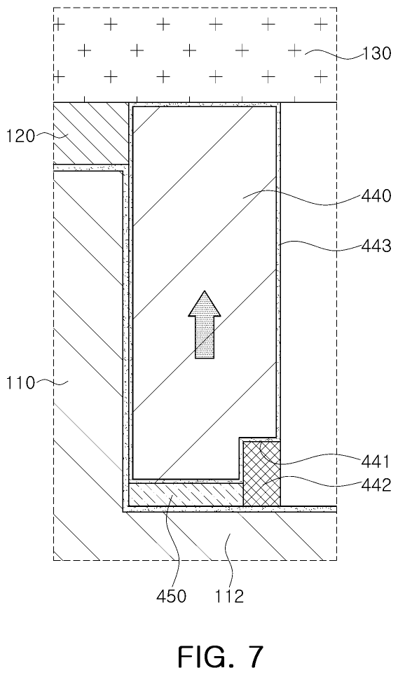

FIG. 7 is a configuration diagram illustrating an electrostatic chuck according to an example embodiment.

Referring to FIG. 7, a sealant 440 is disposed on an upper portion of a thermal pad 450 disposed on the upper surface of the step portion 112. The thermal pad 450 is disposed on the upper surface of the step portion 112 of the electrostatic chuck body 110, and the sealant 440 may have an installation groove 441 in which an O-ring 442 is installed, in a lower end portion. A coating layer 443 may be formed on an outer surface of the sealant 440. The coating layer 443 may be formed after the sealant 440 is installed to be disposed on the thermal pad 450. Then, the O-ring 442 may be installed to be inserted into the installation groove 441.

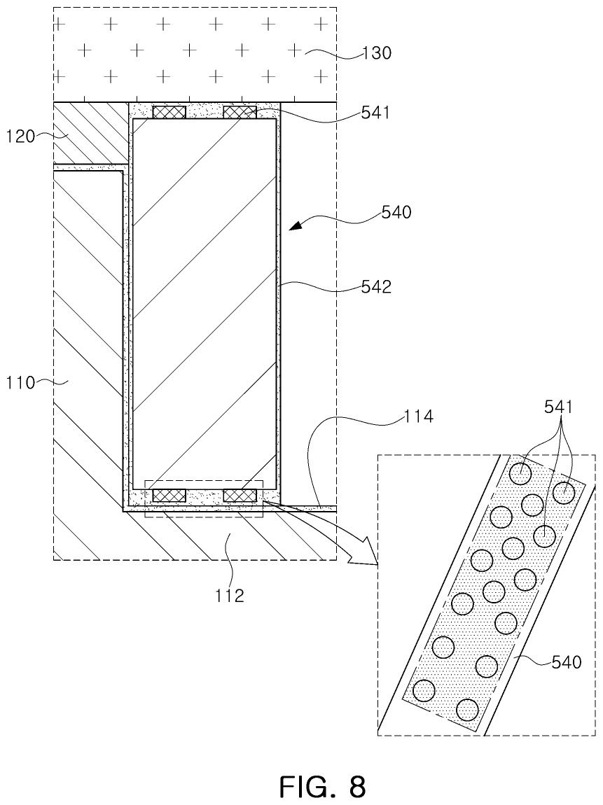

FIG. 8 is a configuration diagram illustrating an electrostatic chuck according to an example embodiment.

Referring to FIG. 8, a sealant 540 may have a plurality of protrusions 541 on the upper and/or lower surfaces. The plurality of protrusions 541 may be spaced apart from each other, and the height of the protrusions 541 may be 5 μm to 20 μm. A coating layer 542 may be formed on the upper and lower surfaces of the sealant 540 to cover the protrusions 541. Also, the coating layer 542 may be formed after the sealant 540 is mounted between the ceramic puck 130 and the step portion 112 of the electrostatic chuck body 110.

The coating layer 542 may be formed by an atomic layer deposition process or a chemical vapor deposition process. As an example, when manufacturing the electrostatic chuck 100, after installing the sealant 540 between the electrostatic chuck body 110 and the ceramic puck 130, the coating layer 542 may be formed using an atomic layer deposition (ALD) method. In this case, the coating layer 542 may be deposited on the sealant 540 by supplying a coating material in the form of a gas. Accordingly, the coating layer 542 may be formed to block a space between the sealant 540 and the ceramic puck 130 and a space between the sealant 540 and the electrostatic chuck body 110.

In a case in which the protrusion 541 is not provided and in a case in which the coating layer 542 is formed to have a thickness of 5 μm or more, the coating layer 542 is not uniformly formed, and a thick portion and a thin portion of the coating layer 542 occur, resulting in causing occurrence of curves in the coating layer 542. In this case, the reaction gas may permeate through spaces between the sealant 540 and the ceramic puck 130 and between the sealant 540 and the body 110. Therefore, to prevent the space between the sealant 540 and the ceramic puck 130 and between the sealant 540 and the body 110 from widening, the protrusions 541 may be disposed, and the coating may be uniform by atomic layer deposition (ALD).

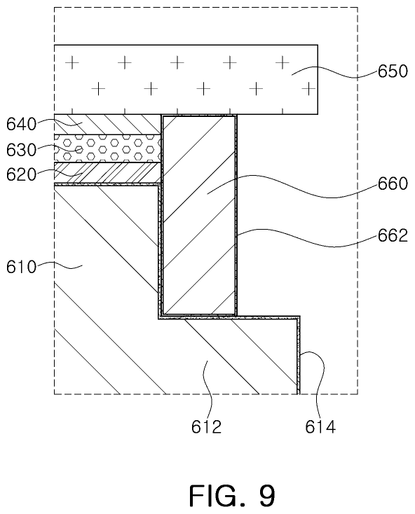

FIG. 9 is a configuration diagram illustrating an electrostatic chuck according to an example embodiment.

Referring to FIG. 9, an electrostatic chuck 600 according to an example embodiment includes an electrostatic chuck body 610, a first adhesive layer 620, a heater 630, a second adhesive layer 640, a ceramic puck 650 and a sealant 660.

The electrostatic chuck body 610 may have a step portion 612 protruding in a radial direction on a lower end thereof. As an example, the electrostatic chuck body 610 may be formed of aluminum. As an example, a protective layer 614 may be provided on the surface of the electrostatic chuck body 610. The protective layer 614 may be formed of, for example, aluminum oxide.

The first adhesive layer 620 is disposed on the upper surface of the electrostatic chuck body 610. As an example, the first adhesive layer 620 bonds the heater 630 to the upper portion of the electrostatic chuck body 620. The first adhesive layer 620 may be a ceramic bond.

The heater 630 is adhered to the first adhesive layer 620 and may serve to heat a wafer that is seated on an upper portion of the ceramic puck 650. The heater 630 may have a size smaller than the size of the ceramic puck 650 and may be disposed so as not to protrude from the upper surface of the electrostatic chuck body 610.

The second adhesive layer 640 is disposed on the upper surface of the heater 630. As an example, the second adhesive layer 640 adheres the ceramic puck 650 to the upper portion of the heater 630. The second adhesive layer 640 may be a ceramic bond.

The ceramic puck 650 is bonded to the second adhesive layer 640 and is disposed in such a manner that the edge thereof protrudes from the upper surface of the electrostatic chuck body 610. As an example, a wafer is seated on the upper surface of the ceramic puck 650 during the process.

The sealant 660 is disposed between the step portion 612 and the edge of the ceramic puck 650 to prevent reaction gas from permeating into the first and second adhesive layers 620 and 640. As an example, the sealant 660 may be formed of a metal material, a ceramic material, a metal-ceramic composite, and/or a polymer-ceramic composite. When the sealant 660 is formed of a metal material, the sealant 660 may be formed of aluminum and/or stainless steel. When the sealant 660 is formed of a ceramic material, the sealant 660 may be formed of aluminum nitride (AlN), aluminum oxide (Al₂O₃), yttrium oxide (Y₂O₃), silicon oxide (SiO₂), silicon carbide (SiC), and Yttrium Aluminum Garnet (YAG). When the sealant 660 is formed of a metal-ceramic composite, the sealant 660 may be formed of an aluminum-silicon carbide composite material. When the sealant 660 includes a polymer-ceramic composite, the sealant 660 may include a silicon-aluminum oxide composite and/or a silicon-aluminum nitride composite.

The sealant 660 may be provided with a coating layer 662 on the outer surface. As an example, the coating layer 662 may be formed of a metal oxide (Al₂O₃, Y₂O₃, YAG, ZrO₂, TiO₂, etc.) including a single rare earth oxide, and a multi-layer heterogeneous metal oxide (Al₂O₃—Y₂O₃, Al₂O₃—TiO₂, etc.). The coating layer 662 may be formed by an atomic layer deposition process or a chemical vapor deposition process.

The sealant 660 may have a circular ring shape, for example, may have a rectangular cross-section. In addition, the sealant 660 is inserted and disposed in a space disposed on the step portion 612 of the electrostatic chuck body 610 and a lower portion of the edge of the ceramic puck 650, to prevent permeation of the reaction gas into the first and second adhesive layers 620 and 640. The sealant 660 may have a circular annular shape formed of a plurality of seals 661. As an example, the plurality of seals 661 may include coupling portions 661a that are formed stepwise on mutually coupled portions. For example, the plurality of seals 661 may include three, and the coupling portions 661a may be disposed on opposite ends of the three seals 661. In addition, a plurality of seals 661 may be coupled as the coupling portions 661a facing each other are displaced vertically.

As described above, since the sealant 660 includes a metal material, a ceramic material, a metal-ceramic composite, and/or a polymer-ceramic composite, thermal conductivity and corrosion resistance may be increased. Accordingly, the replacement frequency of the sealant 660 may be reduced. In addition, the temperature at the edge of the electrostatic chuck 600 may be prevented from excessively rising. In addition, since the coating layer 662 is provided on the outer surface of the sealant 660, thermal conductivity may be increased by increasing contact areas between the sealant 660, the electrostatic chuck body 610, and the ceramic puck 650. Furthermore, permeation of the reaction gas into the first and second adhesive layers 620 and 640 may be prevented.

As set forth above, an electrostatic chuck in which the process yield at the edge of a substrate may be increased by suppressing a rise in temperature at the edge may be provided.

While example embodiments have been illustrated and described above, it will be apparent to those skilled in the art that modifications and variations could be made without departing from the scope of the present inventive concept.

What is claimed is:

1. An electrostatic chuck, comprising:
an electrostatic chuck body including a lower end and a step portion protruding therefrom;
an adhesive layer disposed on an upper surface of the electrostatic chuck body;
a ceramic puck adhered to the adhesive layer and having an edge protruding from the upper surface of the electrostatic chuck body; and
a sealant disposed between the step portion and the edge of the ceramic puck and configured to block reaction gas from permeating into the adhesive layer,
wherein the sealant includes a coating layer disposed on an external surface thereof, and
wherein the coating layer includes a metal oxide including a single rare earth oxide and/or a multilayer heterogeneous metal oxide.

2. The electrostatic chuck of claim 1, wherein the sealant includes a metal material, a ceramic material, a metal-ceramic composite, and/or a polymer-ceramic composite.

3. The electrostatic chuck of claim 2, wherein the metal material includes aluminum and/or stainless steel.

4. The electrostatic chuck of claim 2, wherein the ceramic material includes aluminum nitride (AlN), aluminum oxide (Al₂O₃), yttrium oxide (Y₂O₃), silicon oxide (SiO₂), silicon carbide (SiC), and/or Yttrium Aluminum Garnet (YAG).

5. The electrostatic chuck of claim 2, wherein the metal-ceramic composite is an aluminum-silicon carbide composite.

6. The electrostatic chuck of claim 2, wherein the polymer-ceramic composite includes a silicon-aluminum oxide composite and/or a silicon-aluminum nitride composite.

7. The electrostatic chuck of claim 1, wherein the electrostatic chuck body includes a protective layer disposed on a surface thereof, and
wherein the protective layer incudes an aluminum oxide material.

8. The electrostatic chuck of claim 1, wherein the sealant has a circular ring shape.

9. The electrostatic chuck of claim 8, wherein the sealant has a circular ring shape formed of a plurality of seals.

10. The electrostatic chuck of claim 9, wherein the plurality of seals include a coupling portion formed stepwise on a mutually coupled portion.

11. The electrostatic chuck of claim 1, wherein the sealant includes a first sealant having a first inclined surface on an upper end, and a second sealant coupled to the first sealant and having a second inclined surface in contact with the first inclined surface.

12. The electrostatic chuck of claim 1, wherein the sealant is disposed on a thermal pad disposed on an upper surface of the step portion of the electrostatic chuck body.

13. The electrostatic chuck of claim 12, wherein the sealant includes an installation groove in which an O-ring is installed, in a lower end portion.

14. The electrostatic chuck of claim 1, wherein upper and/or lower surfaces of the sealant includes a plurality of protrusions.

15. The electrostatic chuck of claim 14, wherein the protrusion includes a coating layer having a height of 5 μm to 20 μm.

16. The electrostatic chuck of claim 1, further comprising a heater embedded in the adhesive layer.

17. The electrostatic chuck of claim 16, wherein the adhesive layer includes a first adhesive layer disposed between the heater and the electrostatic chuck body, and a second adhesive layer disposed between the heater and the ceramic puck.

18. An electrostatic chuck, comprising:
an electrostatic chuck body including a lower end and a step portion protruding therefrom;
an adhesive layer disposed on an upper surface of the electrostatic chuck body;
a ceramic puck adhered to the adhesive layer and having an edge protruding from the upper surface of the electrostatic chuck body; and
a sealant disposed between the step portion and the edge of the ceramic puck and configured to block reaction gas from permeating into the adhesive layer,
wherein the sealant includes a metal material, a ceramic material, a metal-ceramic composite, and/or a polymer-ceramic composite.

19. The electrostatic chuck of claim 18, wherein the metal material includes aluminum and/or stainless steel, and
wherein the ceramic material includes aluminum nitride (AlN), aluminum oxide (Al₂O₃), yttrium oxide (Y₂O₃), silicon oxide (SiO₂), silicon carbide (SiC), and/or Yttrium Aluminum Garnet (YAG).

20. The electrostatic chuck of claim 18, wherein the metal-ceramic composite is an aluminum-silicon carbide composite, and
wherein the polymer-ceramic composite includes a silicon-aluminum oxide composite and/or a silicon-aluminum nitride composite.
